(19) United States
(12) Patent Application Publication
(10) Pub. No.: US 2011/0266562 A1
(43) Pub. Date: Nov. 3, 2011

(54) GLASS SUBSTRATE WITH AN ELECTRODE, ESPECIALLY A SUBSTRATE INTENDED FOR AN ORGANIC LIGHT-EMITTING DIODE DEVICE

(75) Inventors: Arnaud Huignard, Compiegne (FR); Julien Sellier, Paris (FR); Guillaume Lecamp, Paris (FR)

(73) Assignee: SAINT-GOBAIN GLASS FRANCE, Courbevoie (FR)

(21) Appl. No.: 13/125,334

(22) PCT Filed: Oct. 22, 2009
(86) PCT No.: PCT/FR2009/052027

§ 371 Date: Jul. 21, 2011

(30) Foreign Application Priority Data
Oct. 24, 2008 (FR) 0857237

(51) Int. Cl. H01L 33/62

(52) U.S. Cl. 257/88; 257/98; 257/E33.062

(57) ABSTRACT

A glass substrate includes a first side and a second opposite side, and provided, on its second side, with an electrode which is formed by at least one electrically conductive film, the substrate having, over all of its second side, and through a thickness e extending toward the interior of the substrate in the direction of the first side, a refractive index variation, of the glass, obtained by an ion-exchange treatment, the refractive index at the surface being greater than that of the glass located beyond the thickness e.

The invention relates to a glass substrate provided on one of its sides with an electrode.

The invention will more particularly be described for a structure serving as a support for an OLED (organic light-emitting diode) device.

An OLED comprises an organic electroluminescent material or multilayer and is bounded by two electrodes, one of the electrodes, the anode, being formed by an electrode associated with the glass substrate and the other electrode, the cathode, being arranged on the organic materials opposite the anode.

An OLED is a device which emits light by electroluminescence using the recombination energy of holes, injected from the anode, and electrons, injected from the cathode. In the case of its use in a light-emitting device that emits only on one side, the cathode is then not transparent, and the emitted photons in contrast pass through the transparent anode and the glass substrate that supports the OLED so as to deliver light to the outside of the device.

OLEDs are generally used in display screens, or more recently in lighting devices.

OLEDs have a low light-extraction efficiency: the ratio of the light that actually leaves the glass substrate to the, light emitted by the electroluminescent materials is relatively low, about 0.25.

This effect is a result, on the one hand, of the fact that a quantity of photons are trapped in guided modes between the cathode and the anode, and on the other hand, of the reflection of light within the glass substrate due to the refractive index difference between the glass substrate (n=1.5) and the air outside the device (n=1).

Solutions have therefore been sought to improve the efficiency of OLEDs, namely to increase the extraction efficiency while delivering a white light i.e. emitting certain or even all the wavelengths in the visible spectrum.

Customarily proposed solutions relate to the glass substrate, either at the glass-air interface, geometric optical solutions being spoken of because these solutions most often make use of geometrical optics, or at the glass-anode interface, diffractive optical solutions being spoken of because these solutions customarily make use of diffractive optics.

It is known, as a diffractive optical solution, to provide the glass-anode interface with a structure of periodic asperities forming a diffraction grating. Document US 2004/0227462 describes a diffractive optical solution. For this purpose it discloses an OLED the transparent substrate of which, support of the anode and of the organic film, is textured. The surface of the substrate thus contains projections and pits in alternation the profile of which is followed by the anode and the organic film deposited above.

However, although such a solution is effective for the extraction of monochromatic light, i.e. in a given direction in space, it is not as effective for polychromatic light such as white light for a lighting application.

Furthermore, in this document US 2004/0227462, the profile of the substrate is obtained by applying a photoresist mask onto the surface of the substrate, the pattern of which corresponds to that required for the protrusions, and then etching the surface through the mask. Such a process is not easy to implement industrially on large-area substrates, and is above all too costly, especially for lighting applications.

Document WO 05/081334 provides another diffractive optical solution which consists in covering a planar glass substrate with an embossed polymer film, the subsequently deposited electrode and the organic film following the profile of the polymer film. The wave-shape structure of the film, which may or may not be periodic, is dimensioned such that the distance separating a wave peak from a wave trough is between 0.5 μm and 200 μm.

Nevertheless, with such a solution, many electrical faults have however been observed in the OLEDs.

The object of the invention is therefore to provide an inorganic glass substrate having on one of its sides a transparent electrode, the substrate being intended to form the support of a light-emitting device, in particular an OLED, which is simple, reliable, improves, relative to current solutions, the extraction of light emitted by said device and allows a white light to be delivered.

According to the invention, the glass substrate comprises a first side and a second opposite side, the second side being provided with an electrode which is formed by at least one electrically conductive film. The glass substrate has, over all of its second side, and through a thickness e extending toward the interior of the substrate in the direction of the first side, a refractive index variation, of the glass, obtained by an ion-exchange treatment, the refractive index at the surface being greater than that of the glass located beyond the thickness e (i.e. at a thickness greater than the thickness e measured from the free surface of the substrate, on the exchanged side).

This index variation is obtained by ion exchange. Ion exchange in glass is the ability of certain ions in the glass, in particular alkali-metal ions, to exchange with other ions having different properties, such as polarizability. These other ions are exchanged at the surface of the glass and thus form in the glass near its surface an ionic pattern the refractive index of which is different from that of the glass.

The surface of the glass remains flat enough to prevent electrical contact between the anode and the cathode, which would impair the OLED.

Advantageously, the refractive index varies through the thickness e as far as the surface of the second side, so as to tend toward or equal the refractive index of the electrode. Thus, an index variation, between the surface of the glass and the electrode directly in contact with the glass, of 0.4, or even 0.3, is preferred.

The refractive index variation in the thickness e may correspond to a profile passing from the value of the index of the glass beneath the thickness e (beyond the thickness e) to another index value, directly without an intermediate value.

According to a preferred variant, the refractive index variation in the substrate corresponds to an index gradient, i.e. a variation corresponding to a profile passing via a number of index values. The profile is preferably (approximately) linear. Such a profile is obtained by selecting, in a known way, the glass, especially its diffusion properties, for example the interdiffusion coefficient between silver and sodium.

The index variation is greater than or equal to 0.05, preferably at least equal to 0.08, even at least equal to 0.1.

The substrate advantageously has a refractive index that varies from the thickness of the glass as far as the surface so as to tend toward or equal the refractive index of the electrode.

Thus, when the glass substrate, provided with its electrode, serves as a support for an OLED, the photons, emitted from the OLED, which pass through the electrode and encounter the glass substrate, are deflected from their path to a far lesser extent because the index difference between the electrode and the glass is much smaller. An index gradient is defined as a progressive change in the index of the medium. This medium makes it possible to prevent too much reflection of the light passing through it.

According to one feature, an index variation in the thickness of the glass, advantageously between 1 μm and 100 μm, preferably between 1 μm and 10 μm, and in particular between 1 μm and 5 μm, is enough to direct the light in the substrate at an angle of incidence that ensures optimal transmission of photons from the substrate.

The ion exchange is the exchange of certain ions of the glass with ions chosen from, in combination or not, barium, cesium, and preferably silver or thallium ions. These ions are chosen for their high polarizability relative to the ions that they replace, thereby causing a large variation in the refractive index of the exchange region of the glass.

The use of silver or thallium ions as the dopant ion allows regions to be created having a sufficiently high refractive index, relative to that of the glass, so that, according to the invention, the particular application of electroluminescent devices may be addressed.

The ion exchange is obtained using known techniques. The surface of the glass substrate to be treated is placed in a bath of molten salts of the exchange ions, for example silver nitrate (AgNO₃), at a high temperature, between 200 and 550° C., and for sufficient time depending on the required exchange depth.

Advantageously, the substrate in contact with the bath may simultaneously be subject to an electric field, which preferably varies, mainly depending on the conductivity of the glass substrate and its thickness, between 10 and 100 V. In this case, the substrate may then be subject to another heat treatment, advantageously at a temperature between the exchange temperature and the glass transition temperature of the glass, so as to make the exchange ions diffuse in a direction normal to the side of the substrate provided with the electrode, so as to obtain an index gradient with a linear profile.

The light transmission of the substrate of the invention may be greater than or equal to 80%.

The substrate may be made of an extra-clear glass. Reference may be made to Application WO 04/025334 for the composition of an extra-clear glass. In particular, a soda-lime-silica glass containing less than 0.05% of Fe III (or Fe₂O₃) may be chosen. For example, Diamant glass from Saint-Gobain, (textured or smooth) Albarino glass from Saint-Gobain, Optiwhite glass from Pilkington or B270 glass from Schott may be chosen.

The glass substrate may advantageously have the following composition:

| | |
|---|---|
| SiO₂ | 67.0-73.0%, preferably 70.0-72.0%; |
| Al₂O₃ | 0-3.0%, preferably 0.4-2.0%; |
| CaO | 7.0-13.0%, preferably 8.0-11.0%; |
| MgO | 0-6.0%, preferably 3.0-5.0%; |
| Na₂O | 12.0-16.0%, preferably 13.0-15.0%; |
| K₂O | 0-4.0%; |
| TiO₂ | 0-0.1%; |
| Total iron content | 0-0.03%, preferably 0.005-0.01%; |
| (expressed in Fe₂O₃) | |
| Redox | 0.02-0.4%, preferably 0.02-0.2%; |
| (FeO/total iron content) | |
| Sb₂O₃ | 0-0.3%; |
| CeO₂ | 0-1.5%; and |
| SO₃ | 0-0.8%, preferably 0.2-0.6%. |

The glass substrate according to the invention is preferably used as a support in a light-emitting device, especially an electroluminescent diode device (OLED) comprising an organic film placed between two electrodes, one of the electrodes being formed by the electrode of the glass substrate of the invention.

Such an electroluminescent diode device is for example intended for use in display screens or lighting devices.

The invention will now be described using examples, for illustration purposes only, which in no way limit the scope of the invention, and with the appended drawings, in which:

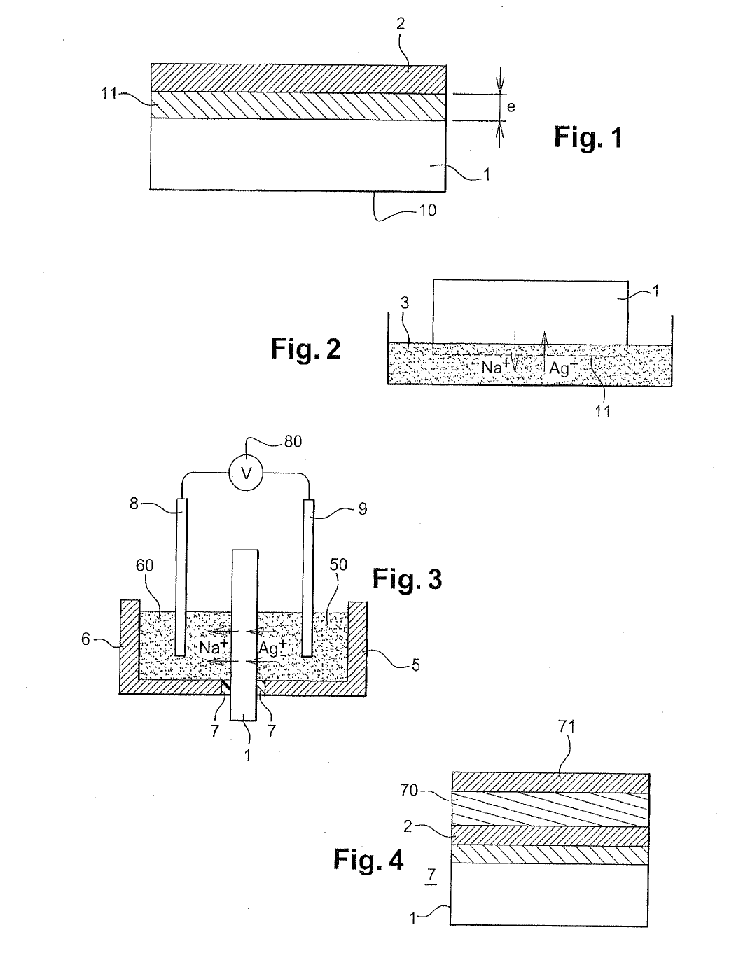

FIG. 1 illustrates a cross section of a glass substrate according to the invention;

FIG. 2 illustrates schematically, according to a first embodiment, the device for implementing the ion-exchange process so as to obtain a substrate the refractive index of which varies through its thickness;

FIG. 3 illustrates schematically, according to a second embodiment, the device for implementing the ion-exchange process so as to obtain a substrate the refractive index of which varies through its thickness; and

FIG. 4 is a cross section of an OLED provided with the substrate of FIG. 1.

The figures are not to scale so as to make them easier to read.

FIG. 1 shows a glass substrate 1 having a thickness especially between 0.7 and 10 mm, comprising, in its largest dimensions, a first side 10 and a second opposite side 11.

The substrate is provided on its second side 11 with an electrode 2 which is formed by at least one thin film of electrically conductive material(s), this film preferably being transparent, with regard to the use of the substrate as a light transmission means.

According to the invention, the substrate 1 has, from its second side 11 as deep as a depth e and over the whole of its surface, a thickness of glass the refractive index of which is modified relative to that of the rest of the body of the substrate.

The thickness e advantageously lies between 1 μm and 100 μm, preferably between 1 μm and 10 μm, and in particular between 1 μm and 5 μm. The refractive index of the glass, which is customarily 1.5, is modified and varies by 0.05 or more, preferably by at least 0.08, or even by at least 0.1.

The substrate retains a substantial light transmission, at least 80%. The light transmission is measured in a known manner in compliance with the ISO 23539:2005 standard.

The index variation is advantageously gradual. It preferably forms an index gradient with a linear profile.

This variation in refractive index is obtained according to the invention using an ion-exchange treatment. Certain ions of the glass, in particular alkali-metal ions, are exchanged with ions such as silver, thallium, barium and/or cesium ions.

Two ion-exchange processing techniques are proposed.

The first technique illustrated in FIG. 2 is carried out by immersing the side 11 of the substrate into a bath 3 containing the material the ions of which are for exchanging. For example, for an exchange of silver ions, the bath contains silver nitrate (AgNO₃).

The immersion of the substrate may be complete with an Al, Ti or Al₂O₃ protective film coating the side opposite the side to be treated and which is removed after the bath, for example by polishing.

The immersion of the substrate may instead by partial and preferably to a depth equal to the full thickness of the substrate, to flush with the side opposite the side to be treated.

The depth to which the silver ions Ag⁺ diffuse into the glass, replacing sodium ions Na⁺, is a function of the time for which the substrate is left in the bath.

After the substrate is removed from the bath it is cooled to room temperature and rinsed copiously in water to remove any residual traces of silver nitrate.

This technique advantageously produces an almost linear index gradient.

The second technique consists of an exchange carried out under an electric field with an optional additional heat treatment step.

FIG. 3 illustrates the device for implementing the electric-field assisted ion-exchange process.

The device comprises two compartments 5 and 6 that face each other and that form respective tanks. The compartments are joined to the substrate 1 via an adhesive 7 which also acts as a seal with respect to the contents of the tanks. One of the compartments contains a bath 50 of AgNO₃ whereas the other compartment is filled with a mixture of KNO₃ (or LiNO₃) and of NaNO₃.

A platinum electrode 8 and a platinum electrode 9 are respectively immersed in each bath 50 and 60, these electrodes being connected to a voltage generator 80.

When an electric field is applied between the electrodes 8 and 9, the alkali-metal ions of the glass move toward the bath 60 and are progressively replaced by the Ag⁺ ions contained in the bath 50 (the direction of migration is shown by the arrows).

As a variant, instead of the AgNO₃ bath, a metallic silver film may be deposited. The latter is deposited by magnetron deposition, CVD deposition, inkjet printing or screen printing. A film forming an electrode is moreover deposited on the opposite side. The electric field is then applied between the silver film and the metallic film. After the exchange, the film forming the electrode is removed by polishing or chemical etching.

The electric field applied between the metallic film or the bath, and the electrode, therefore causes the ion exchange. The ion exchange is carried out at a temperature between 250 and 350° C. The exchange depth is a function of the field strength, the time for which the substrate is subject to this field, and the temperature at which the exchange is carried out. The field lies between 10 and 100 V.

This technique leads to an index variation the profile of which resembles a step, passing abruptly from the value of the index of the glass to a second value without a staggered variation between these two values. For example, it is preferably chosen to carry out such an ion exchange with an extra-clear glass, of 2 mm thickness, at a temperature of 300° C., for a time of 10 h under a field of 10 V/mm. A stepped index variation having an amplitude of 0.1 is obtained.

By finishing the substrate with a heat treatment, the index variation advantageously becomes progressive. This treatment consists in heating the substrate in an oven at a temperature between the ion exchange temperature and the glass transition temperature of the glass. The temperature and the treatment time depend on the required index gradient.

Certain glass compositions will be preferred so that the ion exchange does not cause yellowing of the glass and consequently an unfortunate reduction in the light transmission.

By way of example, the following is a glass composition:

| | |
|---|---|
| SiO₂ | 67.0-73.0%, preferably 70.0-72.0%; |
| Al₂O₃ | 0-3.0%, preferably 0.4-2.0%; |
| CaO | 7.0-13.0%, preferably 8.0-11.0%; |
| MgO | 0-6.0%, preferably 3.0-5.0%; |
| Na₂O | 12.0-16.0%, preferably 13.0-15.0%; |
| K₂O | 0-4.0%; |
| TiO₂ | 0-0.1%; |
| Total iron content | 0-0.03%, preferably 0.005-0.01%; |
| (expressed in Fe₂O₃) | |
| Redox | 0.02-0.4%, preferably 0.02-0.2%; |
| (FeO/total iron content) | |
| Sb₂O₃ | 0-0.3%; |
| CeO₂ | 0-1.5%; and |
| SO₃ | 0-0.8%, preferably 0.2-0.6%. |

The ion exchange process thus allows large areas to be easily treated in an industrially reproducible manner. It allows the glass to be worked on directly, in a manner that is simple, without requiring intermediate and/or additional steps such as film deposition or etching steps.

Furthermore, the unmodified surface finish of the glass substrate ensures that the covering electrode 2 is deposited under both straightforward and usual conditions and with a conventional thickness.

The electrode 2 is formed by a multilayer of electrically conductive materials. It is for example made of an ITO (indium tin oxide) film having a refractive index of about 1.9 or of a dielectric(s)/Ag/dielectric(s) multilayer, generally with a first dielectric in direct contact with the glass having an index of 2.

According to the invention, the variation in the refractive index gradient is such that, deep in the glass, it corresponds to that of the glass (n=1.5) whereas at the surface, it is higher and approaches the refractive index of the first film of the electrode multilayer, near 2.

FIG. 4 shows an OLED 7 comprising the substrate of the invention having the refractive index variation and provided with the electrode 2.

The OLED thus comprises, in succession, the substrate 1 with index variation, serving as a support for the OLED, a first transparent, electrically conductive coating which forms the electrode 2, a film 70 of organic material(s) known per se, and a second electrically conductive coating 71 which forms a second electrode and preferably has, as is known, facing the organic film 70, a reflective surface intended to return the light emitted by the organic film in the opposite direction, that of the transparent substrate.

Example OLEDs were produced for comparison in order to show the beneficial effect of the invention.

The examples all had the same basic OLED elements (transparent electrode, film of organic materials, second electrode, glass support substrate). The glass support or base substrate was a standard glass substrate, of the Albarino® type sold by Saint-Gobain Glass France, that had 5 cm×5 cm sides and a thickness of 2.1 mm.

When this base substrate was untreated, it was a reference substrate (reference example), for the comparative tests, which had a refractive index of 1.52.

Example 1 relates to a base substrate that was subject to a silver ion exchange according to the first technique, having been immersed in a bath of silver nitrate (AgNO₃) for twenty-one hours at a temperature of 345° C.

Example 2 relates to a base substrate that was subject to a thallium ion exchange according to the first technique, having been immersed in a bath of thallium nitrate (TlNO₃) for three hours at a temperature of 400° C.

The table below collates the values obtained for each of the examples: the refractive index of the substrate, the index gradient obtained relative to an untreated reference substrate, the ion-exchange thickness in the substrate, and the extraction efficiency obtained when the substrate of each example is integrated into OLEDs comprising the same elements except for the substrate.

| | Reference | Example | Example |
|---|---|---|---|
| | example | 1 | 2 |
| Refractive | 1.52 | 1.63 | 1.71 |
| index | | | |
| Index | 0 | 0.11 | 0.19 |
| gradient | | | |
| Exchange | 0 | 40 μm | 31 μm |
| thickness | | | |
| Extraction | 23% | 27.5% | 29.5% |
| efficiency | | | |

To calculate the extraction efficiency, first the external quantum efficiency was calculated corresponding to the ratio between the light optical power emitted from the OLED and the electrical power injected into the OLED device. Next, assuming an internal quantum efficiency of 25% for the OLED, the external quantum efficiency was divided by this internal quantum efficiency, here 0.25, to obtain the extraction efficiency.

The substrates of examples 1 and 2 of the invention thus show a relative increase in the light extraction efficiency of over 19% relative to an untreated substrate. The relative increase in extraction efficiency is the ratio between the difference in efficiency between the example of the invention and the reference example, and the efficiency of the reference example. It has moreover been shown that this increase is obtained without degrading other properties of the OLED, especially color variation as a function of the viewing angle of the light.

1. A glass substrate comprising a first side and a second opposite side, and provided, on its second side, with an electrode which is formed by at least one electrically conductive film, said substrate having, over all of its second side, and through a thickness e extending toward the interior of the substrate in the direction of the first side, a refractive index variation, of the glass, obtained by an ion-exchange treatment, the refractive index at the surface being greater than that of the glass located beyond the thickness e.

2. The substrate as claimed in claim 1, wherein the refractive index varies through the thickness e as far as the surface of the second side, so as to tend toward or equal the refractive index of the electrode.

3. The substrate as claimed in claim 1, wherein the refractive index variation in the thickness e corresponds to a profile passing from the value of the index of the glass beneath the thickness e to another index value, directly without an intermediate value or else via a number of index values, the profile preferably being linear.

4. The substrate as claimed in claim 1, wherein the index variation is greater than or equal to 0.05, preferably at least equal to 0.08, even at least equal to 0.1.

5. The substrate as claimed in claim 1, wherein the thickness e of index variation advantageously lies between 1 μm and 100 μM, preferably between 1 μm and 10 μm, and in particular between 1 μm and 5 μm.

6. The substrate as claimed in claim 1, wherein the index variation is obtained by an ion-exchange treatment of the glass using silver and/or thallium, and/or cesium and/or barium ions.

7. The substrate as claimed in claim 1, wherein its light transmission is greater than or equal to 80%.

8. The substrate as claimed in claim 1, wherein the glass substrate has the following composition:

| | |
|---|---|
| SiO₂ | 67.0-73.0%, preferably 70.0-72.0%; |
| Al₂O₃ | 0-3.0%, preferably 0.4-2.0%; |
| CaO | 7.0-13.0%, preferably 8.0-11.0%; |
| MgO | 0-6.0%, preferably 3.0-5.0%; |
| Na₂O | 12.0-16.0%, preferably 13.0-15.0%; |
| K₂O | 0-4.0%; |
| TiO₂ | 0-0.1%; |
| Total iron content | 0-0.03%, preferably 0.005-0.01%; |
| (expressed in Fe₂O₃) | |
| Redox | 0.02-0.4%, preferably 0.02-0.2%; |
| (FeO/total iron content) | |
| Sb₂O₃ | 0-0.3%; |
| CeO₂ | 0-1.5%; and |
| SO₃ | 0-0.8%, preferably 0.2-0.6%. |

9. The substrate as claimed in claim 1, said substrate acting as a support in a light-emitting device, especially an organic light-emitting diode device, the electrode of the substrate forming one of the electrodes of the device.

10. The substrate as claimed in claim 1, said substrate provided in a display screen or a lighting device.
